(19) United States
(12) Patent Application Publication
(10) Pub. No.: US 2012/0274231 A1
(43) Pub. Date: Nov. 1, 2012

(54) Colloidal Silicon Quantum Dot Visible Spectrum Light-Emitting Diode

(76) Inventors: Chang-Ching Tu, Seattle, WA (US); Liang Tang, Vancouver, WA (US); Jiandong Huang, Vancouver, WA (US); Apostolos T. Voutsas, Portland, OR (US)

(21) Appl. No.: 13/094,262

(22) Filed: Apr. 26, 2011

(51) Int. Cl. H05B 37/02; H01L 51/54; H01L 51/56

(52) U.S. Cl. 315/291; 438/22; 257/13; 257/E51.018

(57) ABSTRACT

A method is provided for fabricating a colloidal silicon quantum dot (SiQD) visible spectrum light-emitting diode (LED). The method begins with a transparent first electrode, and a hole-injection layer is formed overlying the first electrode. A hole-transport layer is formed overlying the hole-injection layer, and a SiQD layer overlies the hole-transport layer, where each SiQD has a diameter of less than about 6 nanometers (nm). An electron-transport layer is formed overlying the SiQD layer, and a second electrode is formed overlying the electron-transport layer.

### BACKGROUND OF THE INVENTION

1. Field of the Invention

This invention generally relates to organic light-emitting diodes (OLEDs) and, more particularly, to an OLED fabricated using silicon quantu in dots (SiQDs).

2. Description of the Related Art

Colloidal inorganic semiconductor quantum dots (QDs) with size-tunable band gaps, high photoluminescence (PL) quantum yield, and narrow emission line widths are a good candidate as solution-processable chromophores in a hybrid QD-organic light-emitting diode (QD-OLED) structure. Visible electroluminescence (EL) from the hybrid structure has been reported in group II-VI semiconductor QD systems, such as CdSe, CdZnSe, ZnSe, or CdZnS cores with single or multiple shells. High luminance and high efficiency QD-OLEDs using these II-VI QDs have been recently demonstrated in a display with an active matrix drive backplane. However, for group IV colloidal semiconductor QDs, although there has been significant development in synthesis and characterization. there hasn't been the demonstration of visible EL from these nanomaterials.

It would be advantageous if OLEDs fabricated with silicon QDs (SiQDs) could produce EL across the entire visible spectrum.

### SUMMARY OF THE INVENTION

Silicon QDs (SiQDs) exhibit tunable band gaps due to quantum confinement effect when the dot sizes are within the Bohr exciton radius of bulk Si (around 4.9 nanometers (nm)). Thus, a visible red to blue spectrum can be achieved for electroluminescence (EL) and photoluminescence (PL) applications by adjusting QD radius from approximately 6 nm to 1 nm. Compared to conventional QDs. SiQDs are heavy-metal-free, potentially compatible with well-established Si processing technologies, and can be synthesized from almost inexhaustible starting materials in the earth crust. A substantial number of the device layers can he fabricated using solution-processing methods, including spin-coating and drop-casting. Therefore, the Si QD-OLEDs are potentially low-cost and suitable for large area application, such as flat-panel displays.

Accordingly, a method is provided for fabricating a colloidal silicon quantum dot (SiQD) visible spectrum light-emitting diode (LED). The method begins with a transparent first electrode, and a hole-injection layer is formed overlying the first electrode. A hole-transport layer is formed overlying the hole-injection layer, and an SiQD layer overlies the hole-transport layer, where each SiQD has a diameter of less than about 6 nanometers (nm). An electron-transport layer is formed overlying the SiQD layer, and a second electrode is formed. overlying the electron-transport layer.

In one aspect, the SiQD layer is formed by etching a Si substrate through exposure to a stirred mixture of hydrofluoric acid (HF), methanol, hydrogen peroxide (H₂O₂), and polyoxometalates (POMs). The Si substrate is treated to diluted hydrofluoric acid (HF) in a mixture of water and methanol. In a nitrogen-filled environment, the Si substrate is immersed in a hexane/1-octene mixture with a catalytic amount of chloroplatinic acid. The Si substrate is then ultra-sonicated in hexanes to form a suspension of SiQDs. The suspension of SiQDs is filtered to remove particles larger than 6 nm. Then, the suspension of SiQDs is spin-coated on the underlying layer and vacuum dried.

Additional details of the above-described method, and a colloidal SiQD visible spectrum LED, are provided below.

### BRIEF DESCRIPTION OF THE DRAWINGS

FIG. 1 is a partial cross-sectional view of a colloidal silicon quantum dot (SiQD) visible spectrum light-emitting diode (LED).

FIG. 2 is a graph depicting photoluminescence (FL) intensity as a function of wavelength.

FIGS. 3A and 3B are, respectively, an energy band diagram and EL spectra of the LED of FIG. 1 with blue SiQDs used as the emissive layer.

FIG. 4 depicts an I-V curve associated with the EL spectra measurements of FIG. 3B,

FIG. 5A and 5B are, respectively, an energy band diagram and EL spectra of the LED of FIG. 1 with red SiQDs used as the emissive layer.

FIG. 6 depicts the PL spectra of a (ITO/PEDOT:PSS/poly-TPD) reference device.

FIGS. 7A and 7B are flowcharts illustrating a method for fabricating a colloidal SiQD visible spectrum LED.

### DETAILED DESCRIPTION

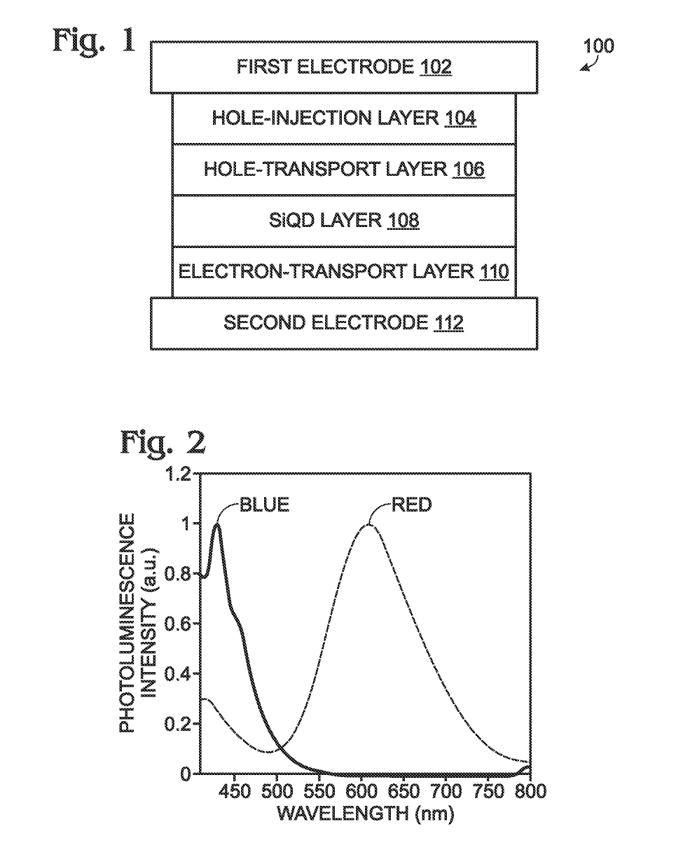

FIG. 1 is a partial cross-sectional view of a colloidal silicon quantum dot (SiQD) visible spectrum light-emitting diode (LED). The LED 100 comprises a first transparent electrode 102, a hole-injection layer 104 overlying the first electrode 102, and a hole-transport layer 106 overlying the hole-injection layer 104. A SiQD layer 108 overlies the hole-transport layer 106, where each SiQD has a diameter of less than about 6 nanometers (nm). An electron-transport layer 110 overlies the SiQD layer 108, and a second electrode 112 overlies the electron-transport layer 110.

In one aspect, the first electrode 102 is indium tin oxide (ITO), and the hole-injection layer 104 is poly(3,4-ethylenedioxythiophene):poly(styrenesulfonate) (PEDOT:PSS). Continuing the example, the hole-transport layer 106 is poly(N,N′-bis(4-butylphenyl)-N,M-bis(phenyl) benzidine (poly-TPD). The electron-transport layer 110 is titanium oxide (TiO₂), and the second electrode 112 is aluminum (Al).

In another aspect, the SiQD layer 108 includes an electron. energy barrier gap between the electron-transport layer 110 and the SiQD layer 108 of less than, or equal to 0.4 electron volts (eV). There is an electron energy barrier gap between the SiQD layer 108 and the hole-transport layer 106 of greater than, or equal to 1.2 eV. Further, there is a. hole energy barrier gap between the hole-transport layer 106 and the SiQD layer 108 of less than, or equal to 0.9 eV, and a hole energy harrier gap between the SiQD layer 108 and the electron-transport layer 110 of greater than, or equal to 1.5 eV. Additional details of the energy barrier gaps are provided below.

### Functional Description.

The SiOs may be synthesized by electrochemical etching of a Si wafer, followed by surface passivation through hydrosilylation and ultra-sonication for dispersion of the Os in solvents. In the electrochemical etching reaction, a p-type boron-doped Si wafer with (100) orientation and 5-20 ohm-cm resistivity was etched by stirring in a mixture of hydrofluoric acid (HF), methanol, hydrogen peroxide (H₂O₂) and polyoxometalates (POMs), where the latter two ingredients function as catalysts. Alternatively, an n-doped or intrinsic Si substrate may be used. A mild etching recipe, e.g., etching current density=10 mA/cm², etching time=2 hours, and a small amount of H₂O₂, may be used to avoid the formation of micro-size pores on the wafer surface. After the electrochemical etching, the wafers are treated with diluted HF in water/methanol mixture for further removal of oxide residues and the formation of purely hydride termination on the surface. Then, in a nitrogen-filled glove box, the wafers are immersed in a hexane/1-octene mixture with a catalytic amount of chloroplatinic acid as catalysts for hydrosilylation reaction, where unsaturated double bonds of 1-octenes form stable covalent bonds with hydrides on the Si surface. With surface passivation by alkyl-ligands, the wafers are ultra-sonicated briefly in hexanes.

FIG. 2 is a graph depicting photoluminescence (PL) intensity as a function of wavelength. The resulting nearly transparent suspension shows bright red PL under 350 nm UV excitation with a peak at 612 nm and a much smaller minor peak in the short wavelength region, as shown in the figure. Passing the red PL suspension through a syringe filter (polypropylene membrane and pore size of 0.2 μm), a clear suspension of SiQDs is obtained, which show blue PL with a narrow line width and a peak at 430 nm. The QD diameter is around 2 nm. The removal of the red peak by simply passing the SiQDs through the syringe filter is likely due to the following reasons: First, during the electrochemical etching, the red PL SiQDs are mostly formed and attached on micro-size structures which are then dispersed into solvents together with SiQDs. Second, the red PL SiQDs tend to form aggregates and get retained when passing through pores of the syringe filter.

In one aspect, the multi-layered light-emitting device of FIG. 1 is composed of indium-tin-oxide (ITO)/poly(3,4-ethylenedioxythiophene):poly(styrenesulfonate) (PEDOT:PSS, 100 nm)/poly(N,N′-bis(4-butylphenyl)-N,N′-bis(phenyl) benzidine (poly-TPD, 50 nm)/SiQDs/titanium dioxide (TiO₂, 65 nm)/Al (100 nm). First, the ITO substrates 102 are sequentially cleaned by ultra-sonication in de-ionized water, isopropanol and acetone, and then treated with oxygen plasma for removing organic residues and enhancing surface hydrophilic property. The hole-injection-layer 104 PEDOT:PSS (2.8 wt % dispersion in H₂O) may be spin-coated at 4000 rpm for 40 seconds and baked in a nitrogen-filled glove box at 120° C. for 30 minutes. Subsequently, the hole-transport-layer 106 poly-TPI) (1.5 wt % in chlorobenzene) may be spin-coated at 2000 rpm for 30 seconds and baked in the same glove box at 110° C. for 30 minutes. For the poly-TPD layer 106, the emissive layer of SiQDs 108 may be spin-coated at 300 rpm for 30 seconds, followed by vacuum drying.

For the electron-transport-layer 110, a TiO₂ precursor sol-gel may be prepared (1.56 mL titanium isopropoxide in 12 mL 2-methoxyethanol) and spin-coated at 3000 rpm for 40 seconds, followed by heating at 80° C. in air. The moisture in air facilitates the precipitation and formation of the amorphous TiO₂ thin film. Finally, a thin film of Al may be RF-sputtered through a shadow mask that defines the active area. Immediately after metallization, fabricated QD-OLEDs 100 may be packaged with glass slides and high vacuum silicone grease. The following I-V curves and EL spectra measurements were performed in an ambient condition.

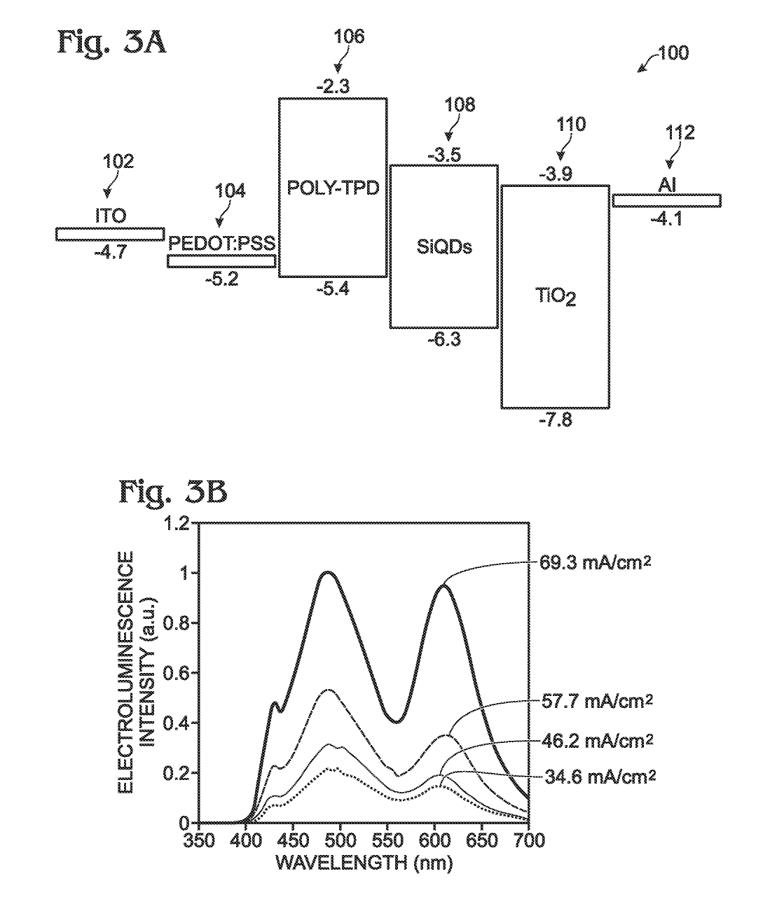

FIG. 3A and 3B are, respectively, an energy band diagram and EL spectra of the LED of FIG. 1 with blue SiQDs used as the emissive layer. The EL spectra were measured with current densities of 34.6, 46.2, 57.7, and 69.3 mA/cm². The optical power increases almost linearly as the current density increases. At the highest input current density, the optical power density of the blue SiQD-OLED was measured to be around 150 nW/cm², which corresponds to an external quantum efficiency (EQE) of around 1×10⁻⁵%.

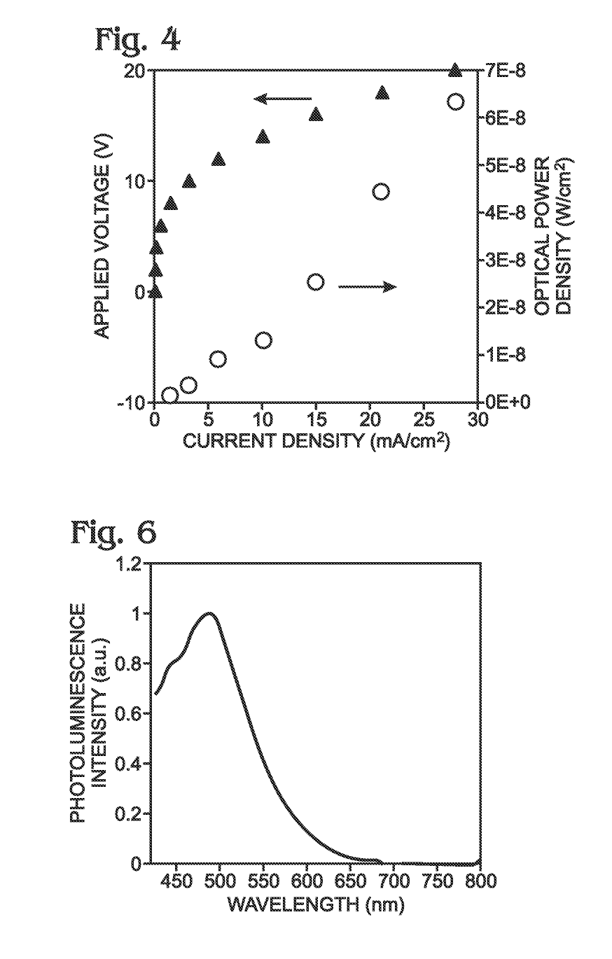

FIG. 4 depicts an I-V curve associated with the EL spectra measurements of FIG. 3B. The I-V curve follows a diode rectifying characteristic.

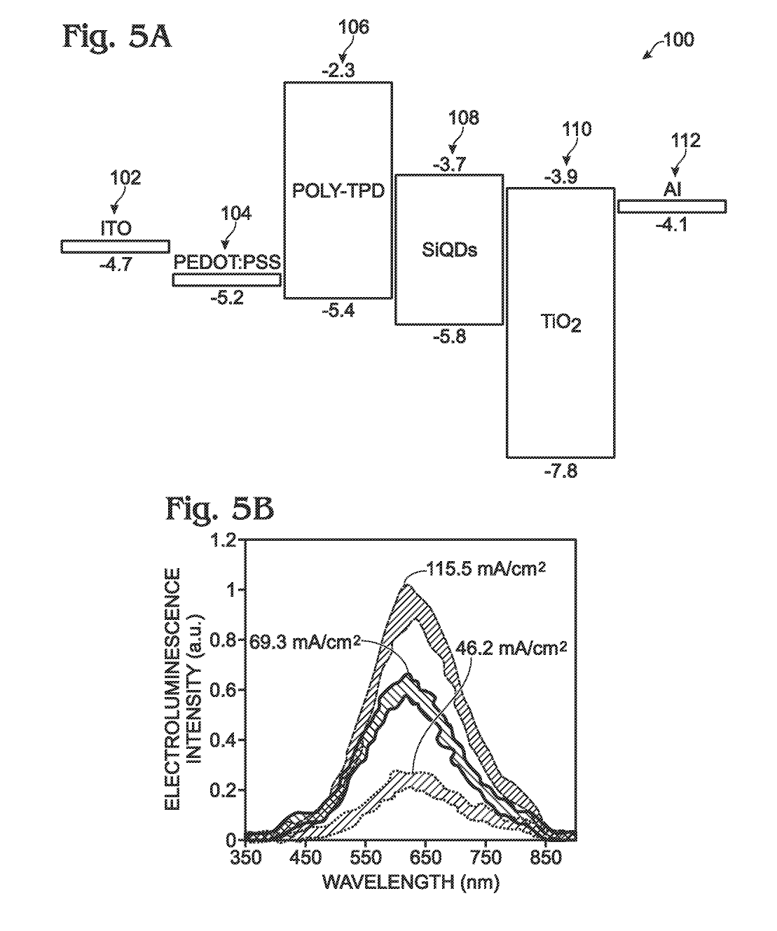

FIG. 5A and 5B are, respectively, an energy band diagram and EL spectra of the LED of FIG. 1 with red SiQDs used as the emissive layer. In order to verify the role of oxygen in red emission SiQDs and observe their EL response, another QD-OLED device was fabricated with the same structure, but using red PL SiQDs (the red PL spectrum in FIG. 2) as the emissive layer. The EL spectra at current densities=46.2, 69.3 and 115.5 mA/cm² of the red SiQD-OLED are depicted in FIG. 5B. The I-V characteristics are similar to the blue SiQD-OLED. However, the quantum efficiency is lower as a result of not only nanocrystalline SiQDs, but also some micro-size Si particles being embedded in the emissive layer. The micro-size particles generate no EL but can absorb the emission from SiQDs.

Second, the EL peak at 618 nm is close to the red SiQD PL peak at 612 nm. Therefore, the “orangish” EL likely comes from carrier recombination in the core quantum confinement states of SiQDs, considering poly-TPD has only blue emission. Furthermore, since the energy band gap of red SiQDs (612 nm) is smaller than the energy difference between electron and hole trap states (590 nm), the oxide states have negligible effect on the EL or PL spectra. Consequently, only one EL peak is observed at 618 nm, rather than multiple peaks as for the blue Si QD-OLED. Finally, at the poly-TPD/SiQDs interface, the CB (C band) energy barrier of the red SiQD-OLED (1.4 eV) is larger than that of the blue SiQD-OLED (1.2 eV) and the VB (V band) energy barrier of the red SiQD-OLED (0.4 eV) is smaller than that of the blue SiQD-OLED (0.9 eV). Therefore, there is better electron-stop and hole-transport at the poly-TPD/SiQDs interface, which leads to much less carrier recombination in the poly-TPD layer for the red SiQD-OLED.

FIG. 6 depicts the PL spectra of a (ITO/PEDOT:PSS/poly-TPD) reference device, in the EL spectra of FIG. 3B, there are three peaks at all current densities, which are 430 nm, 488 nm and 606 nm. The 430 nm EL peak, consistent with the blue PL peak in FIG. 2, is likely due to carrier recombination in the core quantum confinement states of the blue emission SiQDs. The PL spectrum of a reference device (ITO/PEDOT:PSS/poly-TPD) was measured and a peak was observed at 486 nm as shown in FIG. 6. As a result, the 488 nm EL peak can likely be attributed to carrier recombination in the poly-TPD layer. The “orangish” 606 nm peak it is likely due to carrier recombination through the surface trap states of the oxidized blue emission SiQDs. The oxidization may occur as the device is heated in air after the TiO₂ coating and/or during the measurement. The trap states located in the energy band gap lower the radiative recombination energy and thus shift the emission toward longer wavelengths. Similar results in the PL study have been found with SiQDs on porous silicon surface prepared by electrochemical etching of p-type Si wafers, see Wolkin et al., Electronic States and Luminescence in Porous Silicon Quantum Dots: The Role of Oxygen. Upon oxidation, SiQDs with blue or green PL showed a large Stokes shift and the upper limit of the emission energy was 2.1 eV (590 nm) due to localized states in the Si═O bonds, which is close to the 606 nm observed in the above-described EL measurements. However, for the SiQDs that display orange or red emission, the oxide states have a negligible impact on the PL spectrum.

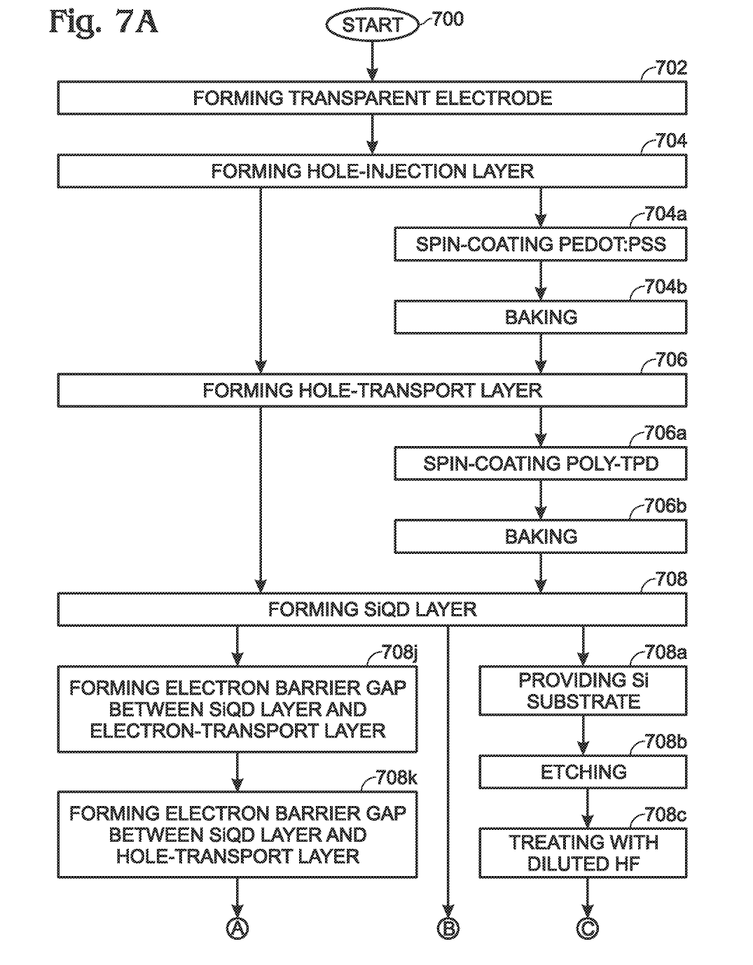

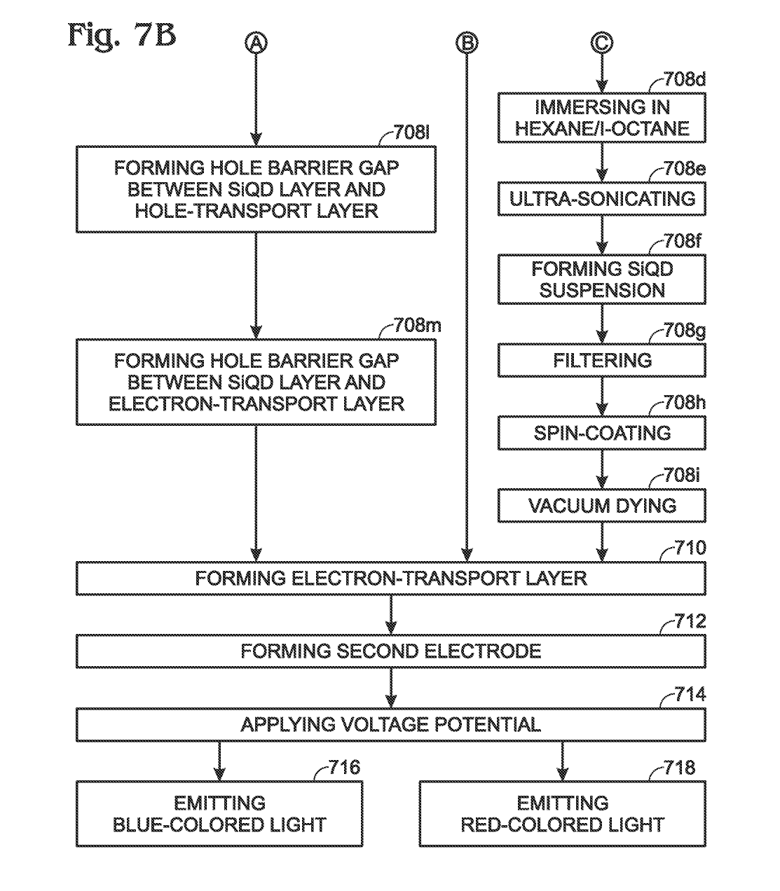

FIGS. 7A and 7B are flowcharts illustrating a method for fabricating a colloidal SiQD visible spectrum LED. Although the method. is depicted as a sequence of numbered steps for clarity, the numbering does not necessarily dictate the order of the steps. It should be understood that some of these steps may be skipped, performed in parallel, or performed without the requirement of maintaining a strict order of sequence. Generally however, the method follows the numeric order of the depicted steps. The method starts at Step 700.

Step 702 forms a transparent first electrode. For example, the first electrode may be ITO. Step 704 forms a hole-injection layer overlying the first electrode. In one aspect, In one aspect, Step 704a spin-coats a layer of poly(3,4-ethylenedioxythiophene):poly(styrenesulfonate) (PEDOT:PSS) at about 4000 RPM for about 40 seconds, to a thickness of about 100 nm. Step 704b bakes in a nitrogen-filled environment at about 120° C. for about 30 minutes. Step 706 forms a hole-transport layer overlying the hole-injection layer. In one aspect, Step 706a spin-coats a layer of poly(N,N′-bis(4-butylphenyl)-N,N′-bis(phenyl) benzidine (poly-TPD) at about 2000 RPM for about 30 second, to a thickness of about 50 nm. Step 706b bakes in a nitrogen-filled environment at about 110° C. for about 30 minutes.

Step 708 forms a SiQD layer overlying the hole-transport layer, where each SiQD has a diameter of less than about 6 nanometers (nm). In one aspect, Step 708 forms the SiQD layer using core/shell SiQDs, where the cores are Si. Some example of a shell are ZnS. ZnO, and CuₓS. Typically, the shell diameter is less than 2 nm.

In another aspect, Step 708a provides a silicon substrate. Step 708b etches the Si substrate through exposure to a stirred mixture of hydrofluoric acid (HF), methanol, hydrogen peroxide (H₂O₂), and polyoxometalates (POMs). Step 708c treats the Si substrate to diluted hydrofluoric acid (HF) in a mixture of water and methanol. In a nitrogen filled environment, Step 708d immerses the Si substrate in a hexane/1-octene mixture with a catalytic amount of chloroplatinic acid. Step 708e ultra-sonicates the Si substrate in hexanes, and Step 708f forms a suspension of SiQDs. Step 708g filters the suspension of SiQDs to remove particles larger than 6 nm. Step 708h spin-coats the suspension of SiQDs at about 300 revolutions per minute (RPM) for about 30 seconds. Step 708i vacuum dries the spin-coated SiQD.

Step 710 forms an electron-transport layer overlying the SiQD layer. In one aspect, Step 710a prepares a TiO₂ precursor sol-gel, in a ratio of about 1.56 milliliters (mL) titanium isopropoxide to about 12 mL of 2-methoxyethanol. Step 710b spin-coats at about 3000 RPM for about 40 seconds, to a thickness of about 65 nm. Step 710c heats at about 80° C. in an ambient air environment. Step 712 forms a second electrode overlying the electron-transport layer. In one aspect, the second electrode is Al. Alternatively, the LED may be fabricated in reverse order, from Step 712 to Step 702.

In one aspect, forming the electron-transport layer in Step 710 includes forming an electron energy barrier gap between the electron-transport and second electrode of 0.2 eV, or less. Forming the hole-injection layer in Step 704 includes forming a hole energy barrier gap between the hole-injection layer and the first electrode of 0.5 eV, or less.

In another aspect, forming the SiQD layer in Step 708 includes the following substeps. Step 708j forms an electron energy barrier gap between the electron-transport layer and the SiQD layer of less than, or equal to 0.4 electron volts (eV). Step 708k forms an electron energy barrier gap between the SiQD layer and the hole-transport layer of greater than, or equal to 1.2 eV. Step 708l forms a hole energy harrier gap between the hole-transport layer and the SiQD layer of less than, or equal to 0.9 electron volts (eV). Step 708m forms a hole energy barrier gap between the SiQD layer and the electron-transport layer of greater than, or equal to 1.5 eV.

More explicitly, the Step 708 forms the SiQD layer using SiQDs having a diameter in a range between 3 and 6 nm, then Step 708j forms an electron energy harrier gap between the electron-transport layer and the SiQD layer of less than, or equal to 0.2 eV. Step 708k forms an electron energy barrier gap between the SiQD layer and the hole-transport layer of greater than, or equal to 1.4 eV. Step 708l forms a hole energy barrier gap between the hole-transport layer and the SiQD layer of less than, or equal to 0.4 eV, and Step 708m forms a hole energy harrier gap between the SiQD layer and the electron-transport layer of greater than, or equal to 2 eV.

Alternatively, if Step 708 forms the SiQD layer using SiQDs having a diameter in a range between 1 and 2 nm, then Step 708j forms an electron energy barrier gap between the electron-transport layer and the SiQD layer of less than, or equal to 0.4 eV. Step 708k forms an electron energy barrier gap between the SiQD layer and the hole-transport layer of greater than, or equal to 1.2 eV. Step 708l forms a hole energy barrier gap between the hole-transport layer and the SiQD layer of less than, or equal to 0.9 eV. Step 708m forms a hole energy barrier gap between the SiQD layer and the electron-transport layer of greater than, or equal to 1.5 eV.

In a different aspect, Step 708 forms the SiQD layer using particles having a diameter in a range of about 1 to 2 nm. Then. Step 714 applies a voltage potential between the first and second electrodes, and in Step 716 the LED emits blue-colored light. Alternatively, if Step 708 forms the SiQD layer using particles having a diameter in a range of about 3 to 6 nm, in Step 718 the LED emits red-colored light.

A SiQD LED device and associated fabrication method have been provided. Examples of particular materials and process steps have been presented to illustrate the invention. However, the invention is not limited to merely these examples. Other variations and embodiments of the invention will occur to those skilled in the art.

We claim:

1. A method for fabricating a colloidal silicon quant dot (SiQD) visible spectrum light-emitting diode (LED), the method comprising:
forming a transparent first electrode;
forming a hole-injection layer overlying the first electrode;
forming a hole-transport layer overlying the hole-injection layer;
forming a SiQD layer overlying the hole-transport layer, where each SiQD has a diameter of less than about 6 nanometers (nn);
forming an electron-transport layer overlying the SiQD layer; and,
forming a second electrode overlying the electron-transport layer.

2. The method of claim 1 wherein forming the SiQD layer includes;
providing a silicon substrate;
etching the Si substrate through exposure to a stirred mixture of hydrofluoric acid (HF), methanol, hydrogen peroxide (H₂O₂), and polyoxometalates (POMs);
treating the Si substrate to diluted hydrofluoric acid (HF) in a mixture of water and methanol;
in a nitrogen filled environment, immersing the Si substrate in a hexaneil-octene, mixture with a catalytic amount of chloroplatinic acid;
ultra-sonicating the Si substrate in hexanes; and,
forming a suspension of SiQDs.

3. The method of claim 2 wherein forming the SiQD layer includes:
filtering the suspension of SiQDs to remove particles larger than 6 nm;
spin-coating the suspension of SiQDs at about 300 revolutions per minute (RPM) for about 30 seconds; and, vacuum drying.

4. The method of claim 1 wherein forming the hole injection layer includes:
spin-coating a layer of poly(3,4-ethylenedioxythiophene):poly(styrenesulfonate) (PEDOT:PSS) at about 4000 RPM for about 40 seconds, to a thickness of about 100 nm; and,
baking in a nitrogen-filled environment at about 120° C. for about 30 minutes.

5. The method of claim 4 wherein forming the hole-transport layer includes:
spin-coating a layer of poly(N,N′-bis(4-butylphenyl)-N,N′-bis(phenyl) benzidine (poly-TPD) at about 2000 RPM for about 30 second, to a thickness of about 50 nm; and,
baked in a nitrogen-filled environment at about 110° C. for about 30 minutes.

6. The method of claim 5 wherein forming the electron-transport layer includes:
preparing a TiO₂ precursor sol-gel, in a ratio of about 1.56 milliliters (mL) titanium isopropoxide to about 12 mL of 2-methoxyethanol;
spin-coating at about 3000 RPM for about 40 seconds, to a thickness of about 65 nm; and,
heating at about 80° C. in an ambient air environment.

7. The method of claim 5 wherein forming the first electrode includes forming an indium tin oxide (ITO) electrode; and, wherein forming the second electrode includes forming an aluminum (Al) electrode.

8. The method of claim 1 wherein forming the SiQD layer includes:
forming an electron energy barrier gap between the electron-transport layer and the SiQD layer of less than, or equal to 0.4 electron volts (eV); and, forming an electron energy barrier gap between the SiQD layer and the hole-transport layer of greater than, or equal to 1.2 eV.

9. The method of claim 1 wherein forming the SiQD layer includes:
forming a hole energy barrier gap between the hole-transport layer and the SiQD layer of less than, or equal to 0.9 electron volts (eV); and,
forming a hole energy barrier gap between the SiQD layer and the electron-transport layer of greater than, or equal to 1.5 eV.

10. The method of claim 1 wherein forming the SiQD layer includes:
using SiQDs having a diameter in a range between 3 and 6 nm;
forming an electron energy barrier gap between the electron-transport layer and the SiQD layer of less than, or equal to 0.2 eV; and,
forming an electron energy barrier gap between the SiQD layer and the hole-transport layer of greater than, or equal to 1.4 eV.

11. The method of claim 1 wherein forming the SiQD layer includes;
using SiQDs having a diameter in a range between 1 and 2 nm;
forming an electron energy barrier gap between the electron-transport layer and the SiQD layer of less than, or equal to 0.4 eV; and, forming an electron barrier gap between the SiQD layer and the hole-transport layer of greater than, or equal to 1.2 eV.

12. The method of claim 1 wherein forming the SiQD layer includes:
using SiQDs having a diameter in a range between 3 and 6 nm;
forming a hole energy barrier gap between the hole-transport layer and the SiQD layer of less than, or equal to 0.4 eV; and,
forming a hole energy barrier gap between the SiQD layer and the electron-transport layer of greater than, or equal to 2 eV.

13. The method of claim 1 wherein forming the SiQD layer includes:
using SiQDs having a diameter in a range between 1 and 2 nm;
forming a hole energy harrier gap between the hole-transport layer and the SiQD layer of less than, or equal to 0.9 eV; and,
forming a hole energy harrier gap between the SiQD layer and the electron-transport layer of greater than, or equal to 1.5 eV.

14. The method of claim 1 wherein forming the SiQD layer includes using particles having a diameter in a range of about 1 to 2 nm;
the method further comprising:
applying a voltage potential between the first and second electrodes; and,
emitting blue-colored light.

15. The method of claim 1 wherein forming the SiQD layer includes using particles having a diameter in a range of about 3 to 6 nm;
the method further comprising:
applying a voltage potential between the first and second electrodes; and,
emitting red-colored light.

16. The method of claim 1 wherein forming the electron-transport layer includes forming an electron energy barrier gap between the electron-transport and second electrode of 0.2 eV, or less; and, wherein forming the hole-injection layer includes forming a hole energy harrier gap between the hole-injection layer and the first electrode of 0.5 eV, or less.

17. The method of claim 1 wherein forming the SiQD layer includes forming core/shell SiQDs, where the cores are Si.

18. A colloidal silicon quantum dot (SiQD) visible spectrum light-emitting diode (LED), the LED comprising:
a first transparent electrode;
a hole-injection layer overlying the first electrode;
a hole-transport layer overlying the hole-injection layer;
a SiQD layer overlying the hole-transport layer, where each SiQD has a diameter of less than about 6 nanometers (nm);
an electron-transport layer overlying the SiQD layer, and,
a second electrode overlying the electron-transport layer.

19. The LED of claim 18 wherein the hole-injection layer is poly(3,4-ethylenedioxythiophene):poly(styrenesulfonate) (PEDOT:PSS).

20. The LED of claim 18 wherein the hole-transport layer is poly(N,N′-bis(4-butylphenyl)-N,N′-bis(phenyl) benzidine (poly-TPD).

21. The LED of claim 18 wherein the electron-transport layer is titanium oxide (TiO₂).

22. The LED of claim 18 wherein the SiQD layer includes:
an electron energy barrier gap between the electron transport layer and the SiQD layer of less than, or equal to 0.4 electron volts (eV); and,
an electron energy barrier gap between the SiQD layer and the hole-transport layer of greater than, or equal to 1.2 eV.

23. The LED of claim 18 wherein the SAW layer includes:
a hole energy barrier gap between the hole-transport layer and the SiQD layer of less than, or equal to 0.9 eV; and,
a hole energy barrier gap between the SiQD layer and the electron-transport layer of greater than, or equal to 1.5 eV.

24. The LED of claim 18 wherein the first electrode is indium tin oxide (ITO); and,
wherein the second electrode is aluminum (Al).
